(19) United States
(12) Patent Application Publication
(10) Pub. No.: US 2017/0062279 A1
(43) Pub. Date: Mar. 2, 2017

(54) TRANSISTOR SET FORMING PROCESS

(71) Applicant: UNITED MICROELECTRONICS CORP., Hsin-Chu City (TW)

(72) Inventors: Sih-Yun Wei, Hsinchu City (TW); Hsueh-Chun Hsiao, Hsinchu County (TW); Tzu-Yun Chang, Hsin-Chu Hsien (TW); Shih-Yin Hsiao, Chiayi County (TW); Ching-Chung Yang, Hsinchu City (TW)

(21) Appl. No.: 14/835,700

(22) Filed: Aug. 25, 2015

(51) Int. Cl. H01L 21/8238; H01L 21/266; H01L 27/092; H01L 29/66; H01L 21/265; H01L 29/167

(52) U.S. Cl. CPC H01L 21/823807; H01L 21/823814; H01L 21/26513; H01L 29/167; H01L 27/0922; H01L 29/66575; H01L 21/266

(57) ABSTRACT

A transistor set forming process includes the following steps. A substrate having a first area and a second area is provided. An implantation process is performed to form a diffusion region of a first transistor in the substrate of the first area and a channel region of a second transistor in the substrate of the second area at the same time.

### BACKGROUND OF THE INVENTION

1. Field of the Invention

The present invention relates generally to a transistor set forming process, and more specifically to a transistor set forming process, which forms a diffusion region of a transistor together with a channel region of another transistor.

2. Description of the Prior Art

A threshold voltage is a voltage required to operate a component in a circuit. For example, a metal oxide field effect transistor (MOSFET) has a gate that operates at a threshold voltage. When the threshold voltage or a higher voltage is applied to the gate, the MOSFET is turned on and provides a conductive path. When the voltage applied to the gate is below the threshold voltage, the MOSFET is turned off. In an integrated circuit, different circuit cells, modules and/or transistors and other devices in the same chip may operate in different threshold voltage regimes.

A low threshold voltage (LVt) cell is a cell that operates in the desired manner at a threshold voltage that is lower than a specified voltage. Different LVt cells may operate at different voltage levels below the specified voltage. Accordingly, more than one family of LVt cells may exist such that a first family of LVt cells operates at a first threshold voltage, and a second family of LVt cells operates at a second threshold voltage, the first and the second threshold voltages both being lower than the specified voltage by different amounts. A family of cells is a collection of cells where the cell circuits may provide different functions but all cells in a family operate at a common threshold voltage. Similarly, a high threshold voltage (HVt) cell is a cell that operates in the desired manner at a threshold voltage that is higher than the specified voltage. More than one family of HVt cells may exist such that a first family of HVt cells operates at a first threshold voltage, and a second family of HVt cells operates at a second threshold voltage, the first and the second threshold voltages both being higher than the specified voltage by different amounts.

### SUMMARY OF THE INVENTION

The present invention provides a transistor set forming process, which forms a diffusion region such as a source/drain extension region of a transistor and a channel region such as a gate channel region of another transistor at the same time, specifically by one same implantation process, thereby simplifying processing steps and saving processing costs. Moreover, improving device reliability and decreasing substrate leakage by selecting dopants such as arsenic.

The present invention provides a transistor set forming process including the following steps. A substrate having a first area and a second area is provided. An implantation process is performed to form a diffusion region of a first transistor in the substrate of the first area and a channel region of a second transistor in the substrate of the second area at the same time.

According to the above, the present invention provides a transistor set forming process, which performs an implantation process on a substrate to form a diffusion region of a first transistor in a first area and a channel region of a second transistor in a second area at the same time. In this way, processing steps such as photomasks covering and implantation processes performing can be simplified and thus save costs. The reliability of formed devices and uniformity of these devices can be improved, and flowing down leakage in the substrate can be decreased by chosen dopants in the diffusion region and the channel region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 schematically depict cross-sectional views of a transistor set forming process according to an embodiment of the present invention.

### DETAILED DESCRIPTION

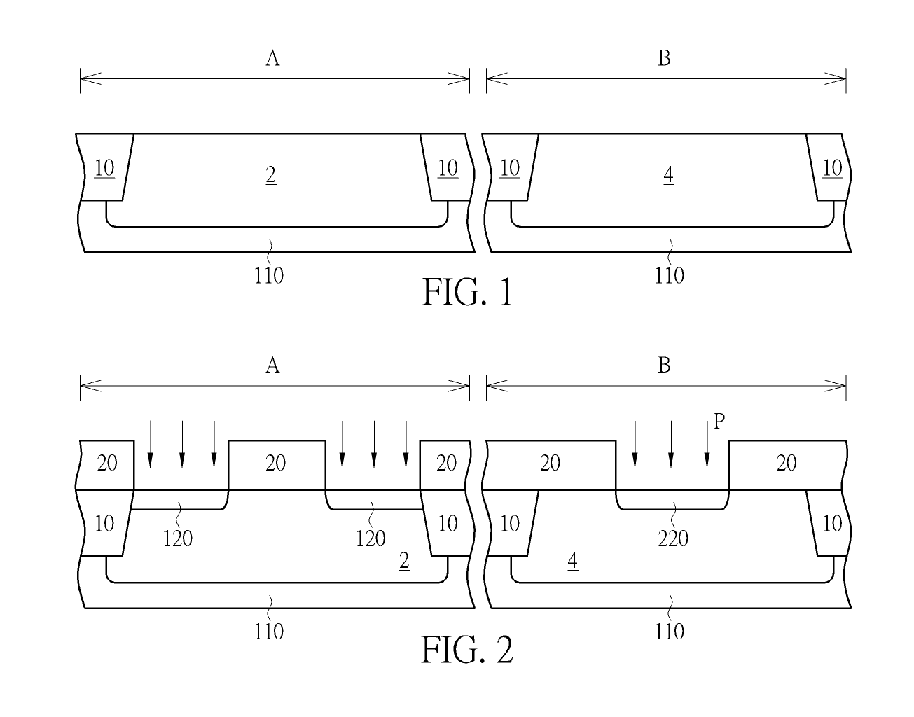

FIGS. 1-6 schematically depict cross-sectional views of a transistor set forming process according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate, a silicon-on-insulator (SOI) substrate or a substrate containing epitaxial layers. The substrate 110 may have a first area A and a second area B. The first area A and the second area B may be both transistor areas for forming different conductive type transistors such as a first transistor is N-type in a first area and a P-type channel region of a second transistor in a second area or a first transistor is P-type in a first area and a N-type channel region of a second transistor in a second area. Preferably, a transistor formed in the first area A has an operating voltage higher than a transistor formed in the second area B. In this case, the first area A is used for forming a medium voltage transistor while the second area B is used for forming a low voltage transistor, but it is not limited thereto.

Optionally, a first well 2 may be formed in the substrate 110 of the first area A, and a second well 4 may be formed in the substrate 110 of the second area B respectively, according to desired formed devices requirements. Furthermore, isolation structures 10 may be formed in the substrate 110 to isolate each transistor. The isolation structures 10 may be shallow trench isolation (STI) structures, formed by a shallow trench isolation (STI) process, but it is not limited thereto.

As shown in FIG. 2, a diffusion region 120 in the substrate 110 of the first area A and a channel region 220 in the substrate 110 of the second area B are both formed at the same time. More precisely, a hard mask (not shown) may cover and be patterned, and thus a patterned hard mask 20 is formed to cover the substrate 110 of the first area A as well as the second area B but exposing regions of the later formed diffusion region 120 and the later formed channel region 220. Then, an implantation process P is performed to form a diffusion region 120 in the exposed substrate 110 of the first area A and a channel region 220 in the exposed substrate 110 of the second area B at the same time. Thereafter, the patterned hard mask 20 is removed.

In this embodiment, the diffusion region 120 is a first source/drain extension region beside a later formed gate, and the channel region 220 is a gate channel region right below another later formed gate, but it is not limited thereto. For example, the diffusion region 120 may be a source/drain instead, depending upon practical requirements. Since the first area A is used for forming a medium voltage transistor while the second area B is used for forming a low voltage transistor, the diffusion region 120 is preferably a first source/drain extension region while the channel region 220 is preferably a gate channel region. That is, the dopant concentration of the diffusion region 120 for forming a medium voltage transistor is similar to the dopant concentration of the channel region 220 for forming a low voltage transistor. This means the implantation process P serves as a lightly doped implantation process in the first area A as well as serves as a threshold voltage tuning implantation process in the second area B.

In a preferred embodiment, the implantation process P may be an As (arsenic) implantation process, when the first area A is N-type transistor area and the second area B is P-type transistor area, thereby a formed device can being more reliable than other dopants such as a P (phosphorous) implantation process. In addition, the implantation process P may be a B (boron) implantation process, when the first area A is P-type transistor area and the second area B is N-type transistor area.

As shown in FIG. 3, a first gate 130 is formed in the first area A as well as the second gate 230 is formed in the second area B after the implantation process P is carried out. More precisely, the first gate 130 is formed on the substrate 110 between the diffusion region 120 and the second gate 230 is formed on the substrate 110 right above the channel region 230. In this case, the first gate 130 and the second gate 230 are formed at the same time by same processes, but it is not limited thereto. In another case, the first gate 130 and the second gate 230 may be formed respectively or sequentially. Since the diffusion region 120 is formed before the first gate 130, thus the first gate 130 can overlap a part d1 of the diffusion region 120, depending upon requirements. In a preferred case, the part d1 of the diffusion region 120 overlaps 10%-40% of a channel length d2 of the first gate 130. Therefore, the diffusion region 120 can have carriers passing between effectively while a turning-on voltage is applied to the first gate 130 without short channel effect occurring.

Above all, by forming the diffusion region 120 before the first gate 130, the part d1 of the diffusion region 120 overlapping the first gate 130 can be designed flexibly without processing restriction. Thus, this improves carrier performance. Due to the diffusion region 120 being doped as As (arsenic) common to the channel region 220 while forming N-type transistors, the reliability of formed devices can be improved and leakage in the substrate 110 flowing downward can be decreased due to dopants such as As (arsenic) not diffusing dramatically and seriously. Therefore, performance of these devices can be uniform. Furthermore, as the diffusion region 120 and the channel region 220 are formed by same implantation process P, photomasks can be reduced and processes can be simplified, thereby saving costs.

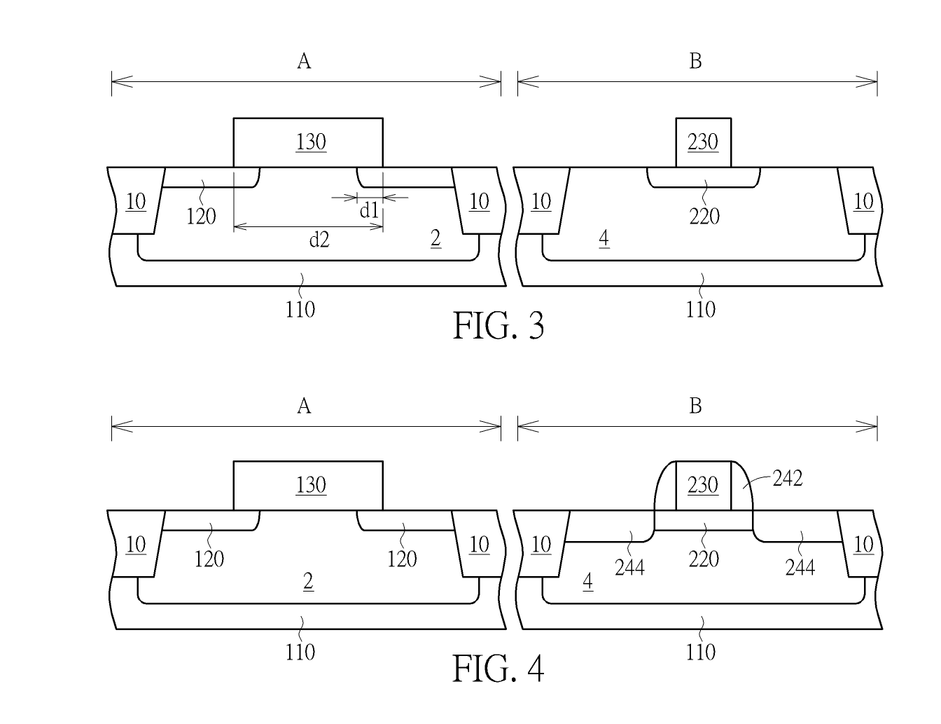

Please refer to FIGS. 4-6, a second source/drain extension region 244, a first source/drain 154 and a second source/drain 254 may be sequentially formed after the first gate 130 and the second gate 230 are formed. The order of forming the second source/drain extension region 244, the first source/drain 154 and the second source/drain 254 is not restricted to the following.

As shown in FIG. 4, an offset 242 may be formed on the substrate 110 of the second area B beside the second gate 230, and thus the second source/drain extension region 244 can be aligned and formed in the substrate 110 of the second area B beside the offset 242.

In this embodiment, the offset 242 is only formed on the substrate 110 of the second area B beside the second gate 230, but it is not restricted thereto. Additionally, the offset 242 can be formed on the substrate 110 of the second area B beside the second gate 230 and on the substrate 110 of the first area A beside the first gate 130 at the same time.

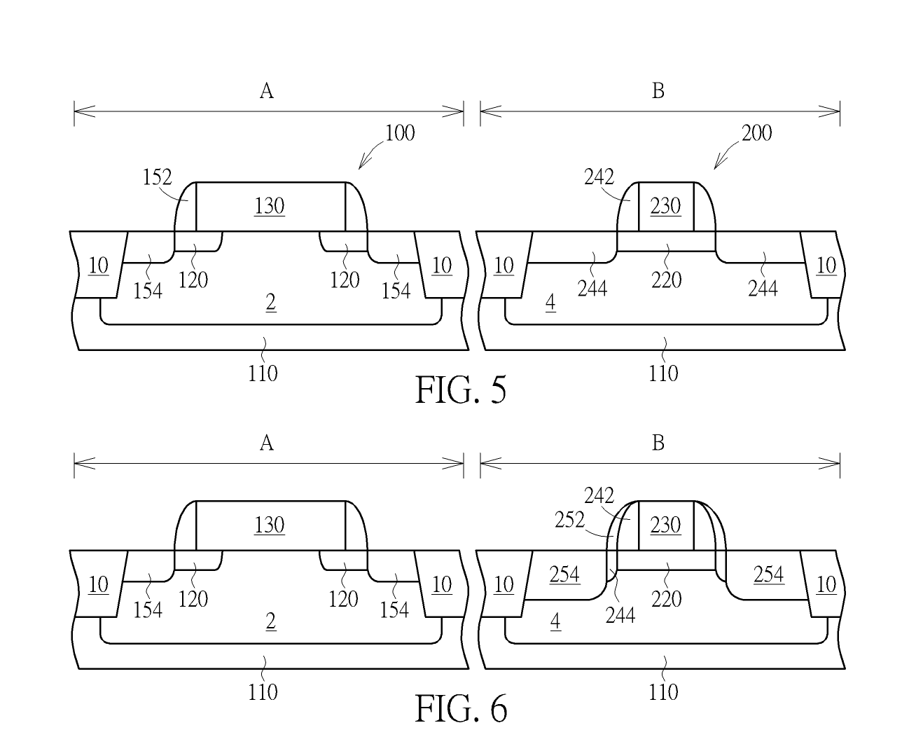

As shown in FIG. 5, a main spacer 152 may be formed on the substrate 110 of the first area A beside the first gate 130, and thus the first source/drain 154 can be aligned and formed in the substrate 110 of the first area A beside the main spacer 152. Thereby, a first transistor 100 being a medium voltage transistor is fabricated. As shown in FIG. 6, a main spacer 252 may be formed on the substrate 110 of the second area B beside the second gate 230, and thus the second source/drain 254 can be aligned and formed in the substrate 110 of the first area B. Thereby, a second transistor 200 being a low voltage transistor is fabricated. In this embodiment, the main spacer 152 and the main spacer 252 are formed respectively. In another embodiment, the main spacer 152 and the main spacer 252 may be formed simultaneously, and then the first source/drain 154 and the second source/drain 254 are formed respectively.

The second source/drain extension region 244, the first source/drain 154 and the second source/drain 254 may be doped with p (phosphorous), B (boron) or other pentevalent or trivalent atoms and with different doping concentration.

It is emphasized that, the diffusion region 120 in the first area A serving as a first source/drain extension region is formed before the first gate 130 is formed; that is, the same time as the channel region 220 in the second area B serving as a gate channel region being formed. However, the second source/drain extension region 244 in the second area B is formed after the second gate 230 is formed.

Thereafter, a sequential semiconductor process can be carried out. For instance, a contact etch stop layer (CESL) (not shown) may conformally cover the first gate 130, the second gate 230 and the substrate 110 followed by an inter-level dielectric (ILD) (not shown) blanketly cover the first gate 130, the second gate 230 and the substrate 110. The inter-level dielectric (ILD) and the contact etch stop layer (CESL) may be patterned to have contact plugs (not shown) filling therein and directly contact the first source/drain 154 and the second source/drain 254. Then, interconnection structures may be fabricated above the inter-level dielectric (ILD) and the contact plugs.

To summarize, the present invention provides a transistor set forming process, which performs an implantation process on a substrate to form a diffusion region of a first transistor in a first area and a channel region of a second transistor in a second area at the same time; then, forms gates such as a first gate between the diffusion region and a second gate right above the channel region. Hence, the part of the diffusion region overlapping the first gate can be adjusted to improve mobility of carriers below the first gate but without short channel effect occurring. Processing steps such as photomasks covering and implantation processes processing can be simplified and thus save costs. The reliability and uniformity of formed devices can be improved and flowing down leakage in the substrate can be decreased by chosen dopants such as As (arsenic) in the diffusion region and the channel region.

Preferably, the first area is a medium voltage transistor area while the second area is a low voltage transistor area for similar dopant concentration of the diffusion region in the first area and the channel region in the second area; the diffusion region is a source/drain extension region and the channel region is a gate channel region. This means the implantation process serves as a lightly doped implantation process in the first area and serves as a threshold voltage tuning implantation process in the second area.

Those skilled in the art will readily observe that numerous modifications and alterations of the device and method may be made while retaining the teachings of the invention. Accordingly, the above disclosure should be construed as limited only by the metes and bounds of the appended claims.

1. A transistor set forming process, comprising:
providing a substrate having a first area and a second area;
performing an implantation process to form a diffusion region of a first transistor in the substrate of the first area and a channel region of a second transistor in the substrate of the second area at the same time; and
forming a second source/drain extension region of the second transistor in the substrate of the second area after the diffusion region is formed.

2. The transistor set forming process according to claim 1, wherein the implantation process comprises an As (arsenic) implantation process.

3. The transistor set forming process according to claim 2, wherein the first transistor comprises an N-type transistor.

4. The transistor set forming process according to claim 1, wherein the implantation process comprises a B (boron) implantation process.

5. The transistor set forming process according to claim 4, wherein the first transistor comprises a P-type transistor.

6. The transistor set forming process according to claim 1, wherein the first transistor comprises a medium voltage transistor while the second transistor comprises a low voltage transistor.

7. The transistor set forming process according to claim 1, wherein the implantation process comprises a threshold voltage tuning implantation process of the second transistor.

8. The transistor set forming process according to claim 1, wherein the diffusion region comprises a first source/drain extension region of the first transistor.

9. The transistor set forming process according to claim 8, further comprising:
forming a first source/drain in the substrate of the first area after the first source/drain extension region is formed.

10. (canceled)

11. The transistor set forming process according to claim 1, further comprising:
forming a first gate on the substrate between the diffusion region after the diffusion region is formed.

12. The transistor set forming process according to claim 11, wherein the first gate overlaps a part of the diffusion region.

13. The transistor set forming process according to claim 11, further comprising:
forming a second gate on the substrate above the channel region while forming the first gate on the substrate between the diffusion region.

14. The transistor set forming process according to claim 13, further comprising:
forming a second source/drain extension region in the substrate of the second area after the second gate is formed.

15. The transistor set forming process according to claim 1, further comprising:
forming a patterned hard mask to cover the substrate of the first area as well as the second area but exposing the diffusion region and the channel region before the implantation process is performed.

16. The transistor set forming process according to claim 1, further comprising:
forming a first well in the substrate of the first area and a second well in the substrate of the second area respectively before the implantation process is performed.

17. The transistor set forming process according to claim 1, wherein the first transistor and the second transistor are different conductive type transistors.
